(19) United States
(12) Patent Application Publication
(10) Pub. No.: US 2023/0223738 A1
(43) Pub. Date: Jul. 13, 2023

(54) LASER LIGHT SOURCE APPARATUS

(71) Applicant: Mitsubishi Electric Corporation, Tokyo (JP)

(72) Inventors: Seiji NAKANO, Tokyo (JP); Norio OKADA, Nagasaki (JP)

(73) Assignee: Mitsubishi Electric Corporation, Tokyo (JP)

(21) Appl. No.: 18/001,007

(22) PCT Filed: Dec. 8, 2020
(86) PCT No.: PCT/JP2020/045723

§ 371 Date: Dec. 7, 2022

(51) Int. Cl. H01S 5/0239; H01S 5/02253; H01S 5/0231; H01S 5/02315; H01S 5/00

(52) U.S. Cl. CPC H01S 5/0239; H01S 5/02253; H01S 5/0231; H01S 5/02315; H01S 5/0085

(57) ABSTRACT

A lead pin (2a,2b) penetrates a metal stem (1). A support block (3) is mounted on the metal stem (1). A dielectric substrate (4) is mounted on a side surface of the support block (3). A signal line (5a,5b) is formed on the dielectric substrate (4). One end of the signal line (5a,5b) is connected to the lead pin (2a,2b). A semiconductor optical modulation device (6) is mounted on the dielectric substrate (4). A conductive wire (8a,8b) connects the other end of the signal line (5a,5b) and the semiconductor optical modulation device (6). The semiconductor optical modulation device (6) includes a plurality of optical modulators (6b,6c) separated from each other.

### FIELD

The present disclosure relates to a laser light source apparatus including a semiconductor optical modulation device.

### BACKGROUND

SNSs, video-sharing services, and the like have been spreading on a global basis, and an increase in capacity of data transfer has been accelerated. Concomitantly, an increase in speed and a decrease in size of optical transceivers have been progressing to cope with higher speed and larger capacity signal transmission in a limited mounting space.

Disclosed as a conventional laser light source apparatus loaded with a semiconductor optical modulation device is one in which a lead pin penetrating a metal stem and AC-GND are converted into a coplanar line and the coplanar line is connected to a semiconductor optical modulation device mounted on a temperature control module (see, e.g., PTL 1).

### CITATION LIST

### Patent Literature

[PTL 1] JP 2011-518381 A

### SUMMARY

### Technical Problem

In a conventional laser light source apparatus, a semiconductor optical modulation device having a single optical modulator has been used, and a method for inputting an electrical signal to the semiconductor optical modulation device has been a single layer driving method. If the optical modulator is shortened, a band can be widened. However, shortening and an extinction ratio are in a trade-off relationship. Accordingly, there has been a problem that an attempt to shorten the optical modulator to widen a band makes it impossible to ensure a sufficient extinction ratio.

The present disclosure has been made to solve the above-described problem, and is directed to obtaining a laser light source apparatus capable of widening a band while ensuring a sufficient extinction ratio.

### Solution to Problem

A laser light source apparatus according to the present disclosure includes: a metal stem; a lead pin penetrating the metal stem; a support block mounted on the metal stem; a dielectric substrate mounted on a side surface of the support block; a signal line formed on the dielectric substrate and having one end connected to the lead pin; a semiconductor optical modulation device mounted on the dielectric substrate; and a conductive wire connecting the other end of the signal line and the semiconductor optical modulation device, wherein the semiconductor optical modulation device includes a plurality of optical modulators separated from each other.

### Advantageous Effects of Invention

In the present disclosure, the semiconductor optical modulation device includes the plurality of optical modulators separated from each other. As a result, each of the optical modulators is more shortened than the conventional optical modulator, and thus decreases in electrostatic capacitance. Therefore, a gain corresponding to a frequency band is improved so that a band is widened. An equivalent extinction ratio to that of the conventional one optical modulator can be ensured by the plurality of electro-absorption optical modulators.

### BRIEF DESCRIPTION OF THE DRAWINGS

FIG. 1 is a perspective view illustrating a laser light source apparatus according to an embodiment 1.

FIG. 2 is a plan view illustrating an optical modulation section in the semiconductor optical modulation device according to the embodiment 1.

FIG. 3 is a diagram illustrating a circuit configuration of the laser light source apparatus according to the embodiment 1.

FIG. 4 is a diagram illustrating a result of a three-dimensional electromagnetic field simulation of a frequency response characteristic of a conventional laser light source apparatus.

FIG. 5 is a diagram illustrating a result of a three-dimensional electromagnetic field simulation of a frequency response characteristic of the laser light source apparatus according to the embodiment 1.

FIG. 6 is a diagram illustrating a circuit configuration of a laser light source apparatus according to an embodiment 2.

FIG. 7 is a plan view illustrating a part of a laser light source apparatus according to an embodiment 3.

FIG. 8 is a cross-sectional view taken along a line I-II illustrated in FIG. 7.

FIG. 9 is a cross-sectional view illustrating a part of a laser light source apparatus according to an embodiment 4.

FIG. 10 is a cross-sectional view illustrating a part of a laser light source apparatus according to an embodiment 5.

FIG. 11 is a perspective view illustrating a laser light source apparatus according to an embodiment 5.

FIG. 12 is a cross-sectional view illustrating a laser light source apparatus according to an embodiment 7.

FIG. 13 is a side view illustrating a laser light source apparatus according to an embodiment 8.

### DESCRIPTION OF EMBODIMENTS

A laser light source apparatus according to the embodiments of the present disclosure will be described with reference to the drawings. The same components will be denoted by the same symbols, and the repeated description thereof may be omitted.

### Embodiment 1

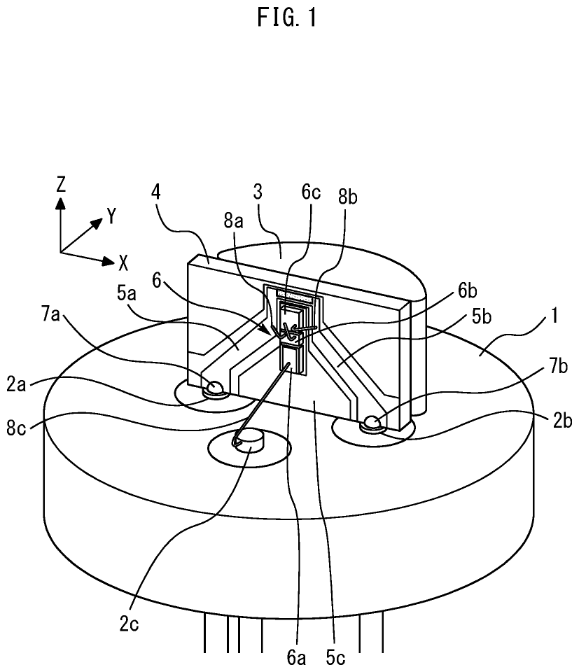

FIG. 1 is a perspective view illustrating a laser light source apparatus according to an embodiment 1. A metal stem 1 is a plate-shaped stem base composed of a metal material obtained by subjecting a surface of a material having a high thermal conductivity such as Cu to Au plating or the like.

Lead pins 2a, 2b, and 2c penetrate the metal stem 1. A support block 3 is mounted on the metal stem 1. The support block 3 is a block composed of a metal material obtained by subjecting a surface of a material having a high thermal conductivity such as Cu to Au plating or the like.

A dielectric substrate 4 is mounted on a side surface of the support block 3. The dielectric substrate 4 is a ceramic plate composed of aluminum nitride (AlN), for example. Differential driving signal lines 5a and 5b and a ground conductor 5c constitute an Au plated and metallized pattern formed on the dielectric substrate 4. Each of the differential driving signal lines 5a and 5b is a coplanar line or a microstrip line, and has an equivalent impedance to an output impedance of a signal generator. The ground conductor 5c is connected to the metal stem 1 with an SnAgCu solder, for example.

A semiconductor optical modulation device 6 is mounted on the dielectric substrate 4. The semiconductor optical modulation device 6 is an optical modulator-integrated laser diode (EAM-LD) obtained by monolithically integrating a distributed feedback laser diode 6a and two electro-absorption optical modulators 6b and 6c. Each of the electro-absorption optical modulators 6b and 6c has an InGaAsP-based quantum well absorption layer, for example.

The differential driving signal lines 5a and 5b have their respective one ends connected to the lead pins 2a and 2b with solders 7a and 7b. Each of the solders 7a and 7b is composed of a material such as SnAgCu. Conductive wires 8a and 8b composed of Au or the like respectively connect the other ends of the differential driving signal lines 5a and 5b and the electro-absorption optical modulators 6b and 6c in the semiconductor optical modulation device 6 to each other. A conductive wire 8c composed of Au or the like connects the lead pin 2c and the distributed feedback laser diode 6a to each other. Ultrasonic vibration crimping, for example, is used for wire bonding.

The metal stem 1 fixes the support block 3, the dielectric substrate 4, and the semiconductor optical modulation device 6. The support block 3 fixes the dielectric substrate 4 and the semiconductor optical modulation device 6. The dielectric substrate 4 fixes the semiconductor optical modulation device 6. Generally, the dielectric substrate 4 is responsible for an electrical insulation function and a heat transfer function. Heat generated in the semiconductor optical modulation device 6 is dissipated to a cooling member (not illustrated) in a negative direction of a Z-axis of the metal stem 1 via the metal stem 1, the support block 3, and the dielectric substrate 4.

The distributed feedback laser diode 6a is supplied with power via the lead pin 2c and the conductive wire 8c, and emits laser light. An electrical signal is applied to the plurality of optical modulators 6b and 6c in the semiconductor optical modulation device 6 via the conductive wires 8a and 8b after being inputted from the lead pins 2a and 2b and transmitted to the differential driving signal lines 5a and 5b, respectively, via the solders 7a and 7b. The metal stem 1, the support block 3, and the ground conductor 5c in the dielectric substrate 4, which are connected to one another, function as AC ground, and an electrical signal inputted to each of the lead pins 2a and 2b is electromagnetically coupled to the metal stem 1.

The laser light emitted by the distributed feedback laser diode 6a is sequentially modulated by the electro-absorption optical modulators 6b and 6c. The modulated laser light is radiated along an optical axis perpendicular to a chip end surface and parallel to a chip main surface from a light emission point of the semiconductor optical modulation device 6.

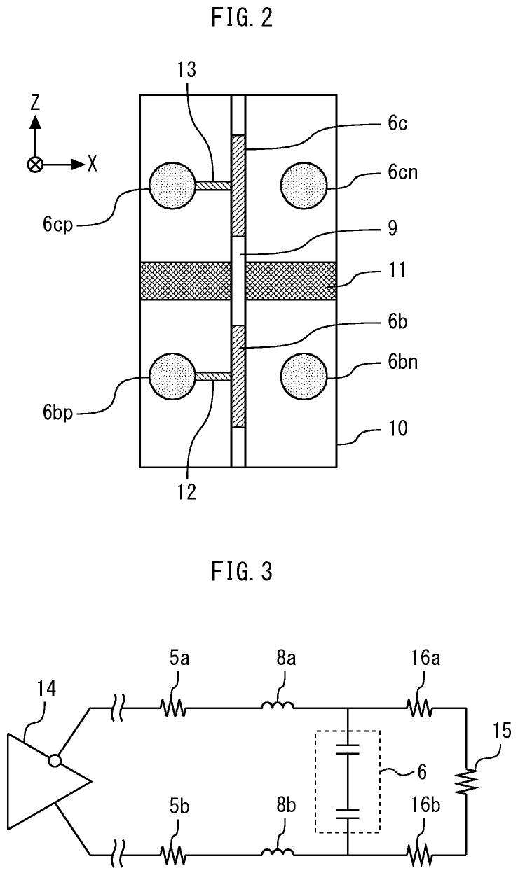

FIG. 2 is a plan view illustrating an optical modulation section in the semiconductor optical modulation device according to the embodiment 1. The electro-absorption optical modulators 6b and 6c and a transparent waveguide 9 are provided on an InP substrate 10. Respective semiconductor layers of the electro-absorption optical modulators 6b and 6c are insulated from each other by an insulating layer 11. Respective absorption layers of the electro-absorption optical modulators 6b and 6c are in optical communication by the transparent waveguide 9. A p-type electrode and a p-type electrode pad 6bp of the electro-absorption optical modulator 6b are electrically connected to each other by a power supply line 12. A p-type electrode and a p-type electrode pad 6cp of the electro-absorption optical modulator 6c are electrically connected to each other by a power supply line 13.

An n-type electrode pad 6bn of the electro-absorption optical modulator 6b and the p-type electrode pad 6cp of the electro-absorption optical modulator 6c are connected to each other by a conductive wire or the like, whereby the electro-absorption optical modulator 6b and the electro-absorption optical modulator 6c are connected in series. The p-type electrode pad 6bp of the electro-absorption optical modulator 6b and an n-type electrode pad 6cn of the electro-absorption optical modulator 6c are respectively wire-connected to the differential driving signal lines 5a and 5b.

FIG. 3 is a diagram illustrating a circuit configuration of the laser light source apparatus according to the embodiment 1. A differential electrical signal outputted from a signal generator 14 is fed to the semiconductor optical modulation device 6 via the differential driving signal lines 5a and 5b and the conductive wires 8a and 8b. To obtain a maximum voltage amplitude from the signal generator 14, a matching resistor 15 is connected in parallel with the semiconductor optical modulation device 6 via signal lines 16a and 16b.

The two electro-absorption optical modulators 6b and 6c in the semiconductor optical modulation device 6 are connected in series. Therefore, letting C1 and C2 be respectively electrostatic capacitances of the electro-absorption optical modulators 6b and 6c, a composite electrostatic capacitance C satisfies C=C1×C2/(C1+C2).

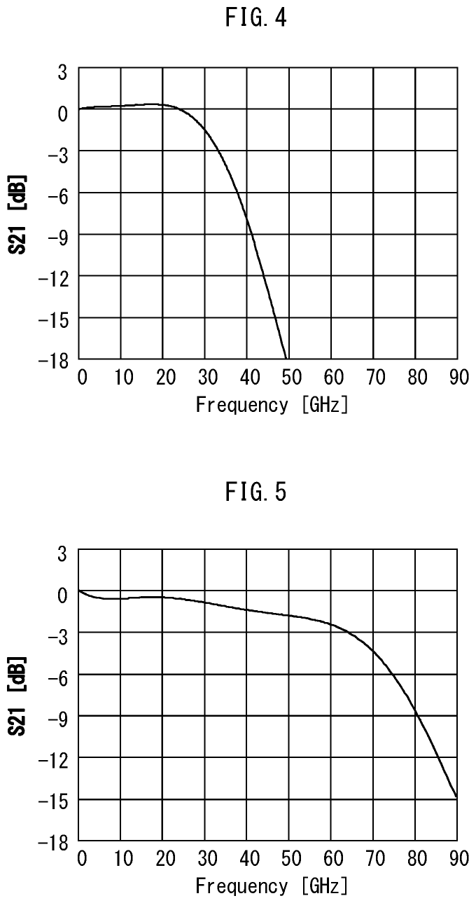

FIG. 4 is a diagram illustrating a result of a three-dimensional electromagnetic field simulation of a frequency response characteristic of a conventional laser light source apparatus. FIG. 5 is a diagram illustrating a result of a three-dimensional electromagnetic field simulation of a frequency response characteristic of the laser light source apparatus according to the embodiment 1. A vertical axis represents a pass characteristic S21. In the conventional laser light source apparatus, the number of optical modulators is one. In the embodiment 1, two optical modulators each having a length that is half that of a conventional optical modulator are connected in series. Although a 3 dB passband (a cutoff frequency) is 33 GHz in the conventional laser light source apparatus, a 3 dB passband is 63 GHz in the present embodiment. Therefore, it can be seen that a gain is improved in a high frequency band in the present embodiment.

As described above, in the present embodiment, the semiconductor optical modulation device 6 includes the plurality of electro-absorption optical modulators 6b and 6c separated from each other. As a result, each of the optical modulators is more shortened than the conventional optical modulator, and thus decreases in electrostatic capacitance. Therefore, a gain corresponding to a frequency band is improved so that a band is widened. An equivalent extinction ratio to that of the conventional one optical modulator can be ensured by the plurality of electro-absorption optical modulators 6b and 6c.

The plurality of electro-absorption optical modulators 6b and 6c are connected in series between the first and second differential driving signal lines 5a and 5b that each feed a differential signal to the semiconductor optical modulation device 6. A method for inputting an electrical signal to the semiconductor optical modulation device 6 is thus a differential driving method. Accordingly, the plurality of electro-absorption optical modulators 6b and 6c can be driven at an equivalent voltage to the conventional one.

In the present embodiment, a temperature control module that has been provided in a conventional technique is not used, thereby making it possible to reduce cost and reduce assembly takt time by reducing the number of members. A temperature control module may be mounted on the metal stem 1 or the side surface of the support block 3, for example, if necessary, depending on a use environment.

### Embodiment 2

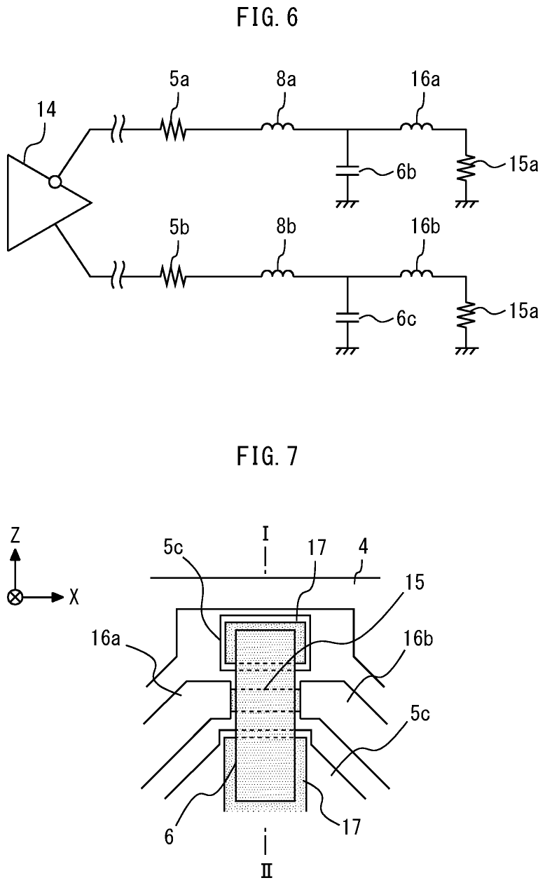

FIG. 6 is a diagram illustrating a circuit configuration of a laser light source apparatus according to an embodiment 2. An electro-absorption optical modulator 6b is connected between a first differential driving signal line 5a and a grounding point. An electro-absorption optical modulator 6c is connected between a second differential driving signal line 5b and a grounding point. Matching resistors 15a and 15b are respectively connected in parallel with the electro-absorption optical modulators 6b and 6c. Even when the electro-absorption optical modulators 6b and 6c and the first and second differential driving signal lines 5a and 5b are thus respectively connected to each other, the plurality of electro-absorption optical modulators 6b and 6c can be driven at an equivalent voltage to the conventional one. Other components and effects are similar to those in the embodiment 1.

### Embodiment 3

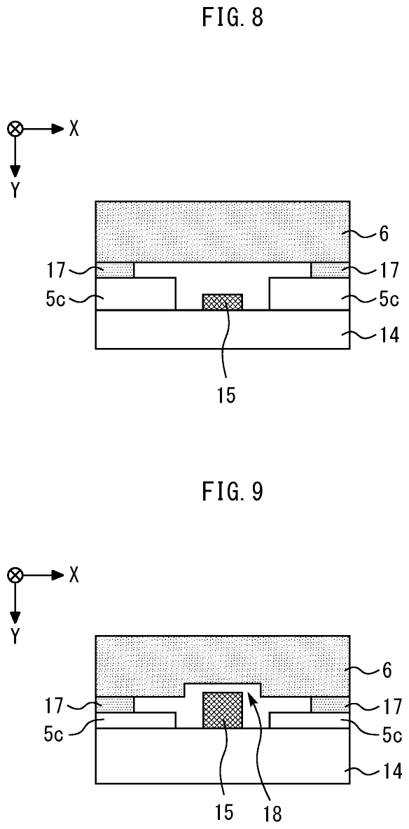

FIG. 7 is a plan view illustrating a part of a laser light source apparatus according to an embodiment 3. FIG. 8 is a cross-sectional view taken along a line I-II illustrated in FIG. 7. A matching resistor 15 is arranged between an upper surface of a dielectric substrate 4 and a lower surface of a semiconductor optical modulation device 6. This eliminates the need to bypass the matching resistor 15 in a positive direction of a Z-axis of the semiconductor optical modulation device 6, and thus eliminates a signal reflection loss due to an impedance mismatch for line. A size in a direction along a Z-axis of the dielectric substrate 4 can be reduced.

The lower surface of the semiconductor optical modulation device 6 is bonded to a ground conductor 5c provided on the upper surface of the dielectric substrate 4 with a solder 17. The ground conductor 5c is divided into two equal parts, and the matching resistor 15 is arranged in a gap between the two equal parts of the ground conductor 5c. As a result, the ground conductor 5c and the matching resistor 15 can be separated from each other. A plating thickness of the ground conductor 5c is larger than that of the matching resistor 15. Accordingly, the matching resistor 15 does not interfere with the semiconductor optical modulation device 6. Other components and effects are similar to those in the embodiments 1 and 2. When the present embodiment is combined with the embodiment 2, the matching resistor 15 is replaced with matching resistors 15a and 15b.

### Embodiment 4

FIG. 9 is a cross-sectional view illustrating a part of a laser light source apparatus according to an embodiment 4. FIG. 9 corresponds to a cross-sectional view taken along a line I-II illustrated in FIG. 7. Although a matching resistor 15 is thicker than a ground conductor 5c, unlike in the embodiment 3, a groove 18 is provided on a lower surface of a semiconductor optical modulation device 6. As a result, the matching resistor 15 does not interfere with the semiconductor optical modulation device 6. Other components and effects are similar to those in the embodiment 3.

### Embodiment 5

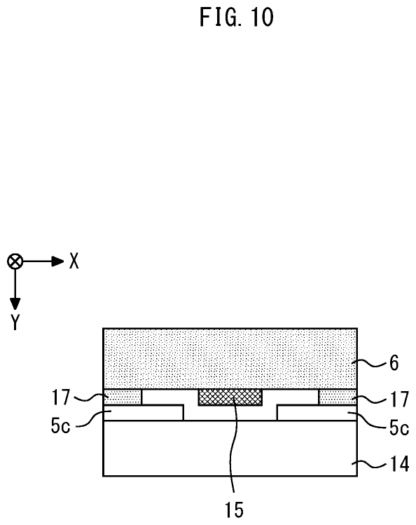

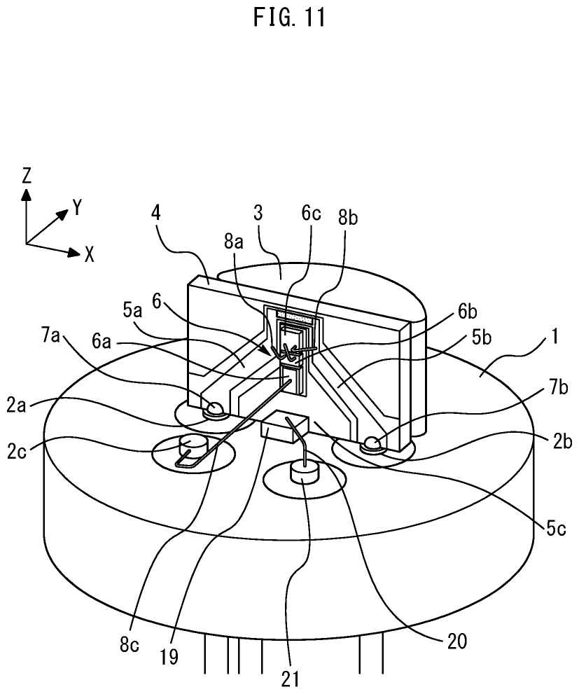

FIG. 10 is a cross-sectional view illustrating a part of a laser light source apparatus according to an embodiment 5. FIG. 10 corresponds to a cross-sectional view taken along a line I-II illustrated in FIG. 7. Although the matching resistor 15 is provided on the upper surface of the dielectric substrate 4 in the embodiment 3, a matching resistor 15 is provided on a lower surface of a semiconductor optical modulation device 6 in the present embodiment. Other components and effects are similar to those in the embodiment 3.

### Embodiment 6

FIG. 11 is a perspective view illustrating a laser light source apparatus according to an embodiment 5. A light receiving device 19 is mounted on a metal stem 1, and is arranged in a negative direction of a Z-axis of a semiconductor optical modulation device 6. The light receiving device 19 is connected to a lead pin 21 by a conductive wire 20. The light receiving device 19 receives back light of the semiconductor optical modulation device 6, and converts the back light into an electrical signal. The electrical signal is transmitted to the lead pin 21 via the connected conductive wire 20. This makes it possible to monitor the intensity of the back light of the semiconductor optical modulation device 6, although the number of lead pins that penetrate the metal stem 1 increases by one. As a result, an LD driving current can be controlled such that a light output is constant. Other components and effects are similar to those in the embodiments 1 to 5.

### Embodiment 7

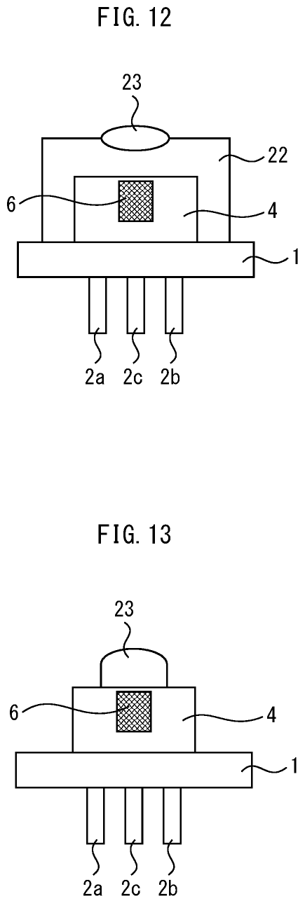

FIG. 12 is a cross-sectional view illustrating a laser light source apparatus according to an embodiment 7. A cap 22 is bonded to a metal stem 1, to airtightly seal a semiconductor optical modulation device 6 or the like. A lens 23 is provided in the cap 22. The lens 23 is glass composed of SiO₂, for example, and collects or collimates laser light emitted from the semiconductor optical modulation device 6. As a result, airtightness of the semiconductor optical modulation device 6 or the like mounted on the metal stem 1 can be ensured. A moisture resistance and a disturbance resistance can also be improved. Other components and effects are similar to those in the embodiments 1 to 6.

### Embodiment 8

FIG. 13 is a side view illustrating a laser light source apparatus according to an embodiment 8. A lens 23 is bonded to a dielectric substrate 4. As a bonding material, an adhesive of epoxy-based resin is used. The lens 23 is glass composed of SiO₂, for example, and collects or collimates laser light emitted from the semiconductor optical modulation device 6. This enables a smaller size than in the embodiment 7. Other components and effects are similar to those in the embodiments 1 to 6.

### REFERENCE SIGNS LIST

1 metal stem; 2a,2b lead pin; 3 support block; 4 dielectric substrate; 5a first differential driving signal line; 5b second differential driving signal line; 5c ground conductor; 6 semiconductor optical modulation device; 6b,6c electro-absorption optical modulator; 8a,8b conductive wire; 15 matching resistor; 18 groove; 19 light receiving device; 22 cap; 23 lens

1. A laser light source apparatus comprising:
a metal stem;
a lead pin penetrating the metal stem;
a support block mounted on the metal stem;
a dielectric substrate mounted on a side surface of the support block;
a signal line formed on the dielectric substrate and having one end connected to the lead pin;
a semiconductor optical modulation device mounted on the dielectric substrate; and
a conductive wire connecting the other end of the signal line and the semiconductor optical modulation device,
wherein the semiconductor optical modulation device includes a plurality of optical modulators separated from each other,
the signal line includes first and second differential driving signal lines,
a differential electrical signal is provided to the semiconductor optical modulation device via the first and second differential driving signal lines, and
the plurality of optical modulators are connected in series between the first and second differential driving signal lines.

2. The laser light source apparatus according to claim 1, wherein absorption layers of the plurality of optical modulators are in optical communication by a transparent waveguide, and
laser light is sequentially modulated by the plurality of optical modulators.

3.-4. (canceled)

5. A laser light source apparatus comprising:
a metal stem;
a lead pin penetrating the metal stem;
a support block mounted on the metal stem;
a dielectric substrate mounted on a side surface of the support block;
a signal line formed on the dielectric substrate and having one end connected to the lead pin;
a semiconductor optical modulation device mounted on the dielectric substrate;
a conductive wire connecting the other end of the signal line and the semiconductor optical modulation device; and
a matching resistor connected in parallel with the semiconductor optical modulation device,
wherein the semiconductor optical modulation device includes a plurality of optical modulators separated from each other, and
the matching resistor is arranged between an upper surface of the dielectric substrate and a lower surface of the semiconductor optical modulation device.

6. The laser light source apparatus according to claim 5, further comprising a ground conductor provided on an upper surface of the dielectric substrate,
wherein the lower surface of the semiconductor optical modulation device is bonded to the ground conductor, and
the matching resistor is arranged in a gap between two divided parts of the ground conductor.

7. The laser light source apparatus according to claim 6, wherein a thickness of the ground conductor is larger than that of the matching resistor.

8. The laser light source apparatus according to claim 5, wherein a groove is provided on the lower surface of the semiconductor optical modulation device.

9. The laser light source apparatus according to claim 5, wherein the matching resistor is provided on the lower surface of the semiconductor optical modulation device.

10. The laser light source apparatus according to claim 1, further comprising a light receiving device mounted on the metal stem and receiving back light of the semiconductor optical modulation device.

11. The laser light source apparatus according to claim 1, further comprising a cap bonded to the metal stem and airtightly sealing the semiconductor optical modulation device; and
a lens provided in the cap and collecting or collimating laser light emitted from the semiconductor optical modulation device.

12. The laser light source apparatus according to claim 1, further comprising a lens bonded to the dielectric substrate and collecting or collimating laser light emitted from the semiconductor optical modulation device.

13. The laser light source apparatus according to claim 5, further comprising a light receiving device mounted on the metal stem and receiving back light of the semiconductor optical modulation device.

14. The laser light source apparatus according to claim 5, further comprising a cap bonded to the metal stem and airtightly sealing the semiconductor optical modulation device; and
a lens provided in the cap and collecting or collimating laser light emitted from the semiconductor optical modulation device.

15. The laser light source apparatus according to claim 5, further comprising a lens bonded to the dielectric substrate and collecting or collimating laser light emitted from the semiconductor optical modulation device.
